(19) United States
(12) Patent Application Publication
(10) Pub. No.: US 2026/0005103 A1
(43) Pub. Date: Jan. 1, 2026

(54) SEMICONDUCTOR PACKAGE ASSEMBLY AND METHOD FOR FORMING THE SAME

(71) Applicant: STATS ChipPAC Pte. Ltd., Singapore (SG)

(72) Inventors: JiSeon LEE, Incheon (KR); BumRyul MAENG, Incheon (KR)

(21) Appl. No.: 19/246,732

(22) Filed: Jun. 24, 2025

(30) Foreign Application Priority Data
Jun. 28, 2024 (CN) 202410860622.5

(51) Int. Cl. H01L 23/473; H01L 23/00; H01L 23/31; H01L 25/00

(52) U.S. Cl. CPC H01L 23/473; H01L 23/3107; H01L 24/32; H01L 25/00; H01L 2224/32245

(57) ABSTRACT

A semiconductor package assembly and a method for forming the same are provided. The assembly includes: a first semiconductor package including a first substrate and a first electronic component mounted on a front surface of the first substrate; a cooling device including a cooling pipe, the cooling pipe being mounted on the first semiconductor package with a lower surface of the cooling pipe thermally coupled to the first electronic component; a second semiconductor package including a second substrate and a second electronic component mounted on a front surface of the second substrate, the second semiconductor package being mounted on the cooling pipe with the second electronic component thermally coupled to an upper surface of the cooling pipe; an encapsulant formed between the front surface of the first substrate and the front surface of the second substrate to encapsulate the first, second electronic components, and a portion of the cooling pipe.

### TECHNICAL FIELD

The present application generally relates to semiconductor technology, and more particularly, to a semiconductor package assembly and a method for forming the same.

### BACKGROUND OF THE INVENTION

The semiconductor industry is constantly faced with complex integration challenges as consumers want their electronics to be smaller, faster and higher performance with more and more functionalities packed into a single device. Nowadays, Package-in-Package (PiP) or Package-on-Package (POP) techniques are introduced. In a typical PiP or POP device, one or more pre-molded semiconductor packages may be mounted onto another semiconductor package. However, when the device is in operation, multiple electronic modules incorporated in the device may generate heat, especially for those high-performance logic chips and memory chips such as central processing units (CPUs), graphics processing units (GPUs) and high bandwidth memories (HBMs). Under such circumstances, the generated heat should be dissipated timely to guarantee good functionalities of the electronic modules. Typically, a heat spreader may be attached on those electronic modules to facilitate heat dissipation. However, an efficiency of the existing heat dissipation methods may still be limited, especially for the device including high-performance chips and with a stacked structure.

Therefore, a need exists for a semiconductor package assembly with an improved heat dissipation capacity.

### SUMMARY OF THE INVENTION

An objective of the present application is to provide a semiconductor package assembly with an improved heat dissipation capacity.

According to an aspect of the present application, a semiconductor package assembly is provided. The semiconductor package assembly may include: a first semiconductor package including a first substrate and at least one first electronic component mounted on a front surface of the first substrate; a cooling device including a cooling pipe, wherein the cooling pipe is mounted on the first semiconductor package with a lower surface of the cooling pipe thermally coupled to the first electronic component; a second semiconductor package including a second substrate and at least one second electronic component mounted on a front surface of the second substrate, wherein the second semiconductor package is mounted on the cooling pipe with the second electronic component thermally coupled to an upper surface of the cooling pipe; and an encapsulant formed between the front surface of the first substrate and the front surface of the second substrate to encapsulate the first electronic component, the second electronic component, and at least a portion of the cooling pipe.

According to another aspect of the present application, a method for forming a semiconductor package assembly is provided. The method may include: providing a first semiconductor package, wherein the first semiconductor package includes a first substrate and at least one first electronic component mounted on a front surface of the first substrate; mounting a cooling pipe of a cooling device on the first semiconductor package with a lower surface of the cooling pipe thermally coupled to the first electronic component; mounting a second semiconductor package on the cooling pipe, wherein the second semiconductor package includes a second substrate and at least one second electronic component mounted on a front surface of the second substrate, and the second electronic component is thermally coupled to an upper surface of the cooling pipe; and forming an encapsulant between the front surface of the first substrate and the front surface of the second substrate to encapsulate the first electronic component, the second electronic component, and at least a portion of the cooling pipe.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1A is a cross-sectional view illustrating a semiconductor package assembly according to an embodiment of the present application.

FIG. 1B is a top view illustrating a first substrate shown in FIG. 1A.

FIG. 1C is a bottom view illustrating a second substrate shown in FIG. 1A.

FIG. 1D is a top view illustrating a cooling pipe shown in FIG. 1A.

FIG. 1E is a perspective view illustrating the cooling pipe shown in FIG. 1A.

FIG. 2 is a cross-sectional view illustrating a semiconductor package assembly according to another embodiment of the present application.

FIG. 3 is a cross-sectional view illustrating a semiconductor package assembly according to another embodiment of the present application.

FIGS. 4A to 4G are cross-sectional views illustrating various steps of a method for forming a semiconductor package assembly according to an embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

To address the heat dissipation issue as mentioned above, a new semiconductor package assembly with a cooling system is provided. In the semiconductor package assembly, two semiconductor packages are attached face-to-face to two opposite sides of a cooling pipe. As the cooling pipe is sandwiched between the two semiconductor packages, electronic components, especially high-performance logic chips which generate more heat, of the two semiconductor packages can directly contact with the cooling pipe, and thus coolant fluid in the cooling pipe can efficiently dissipate heat generated within the semiconductor package assembly.

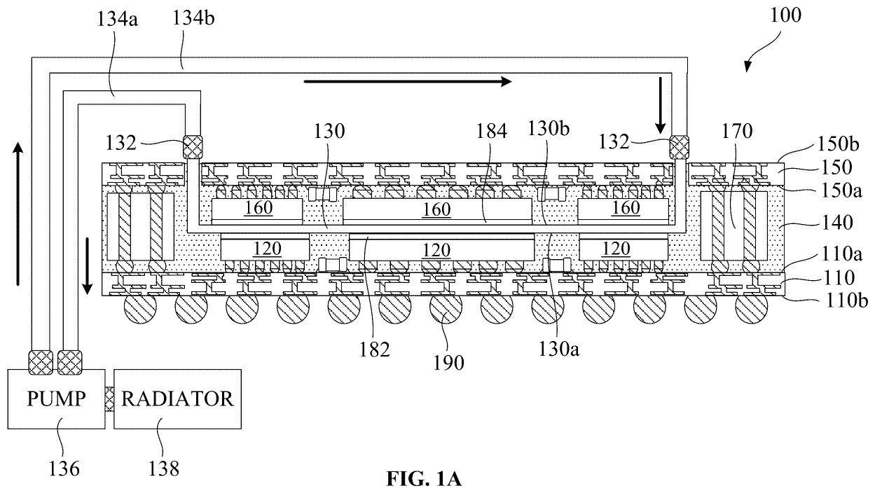

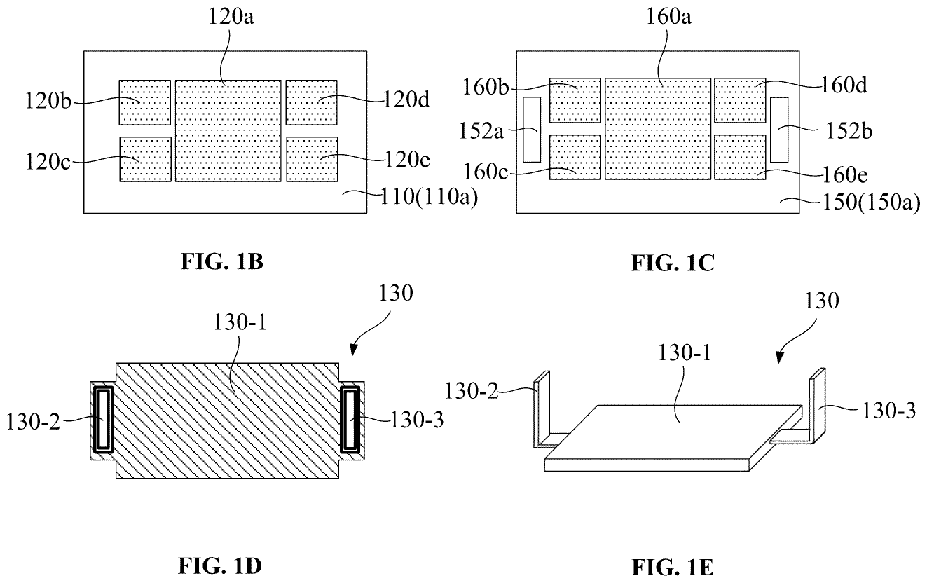

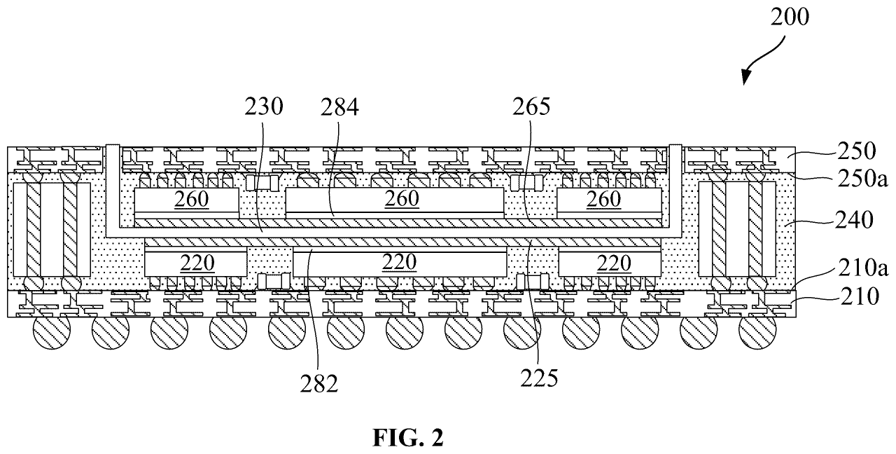

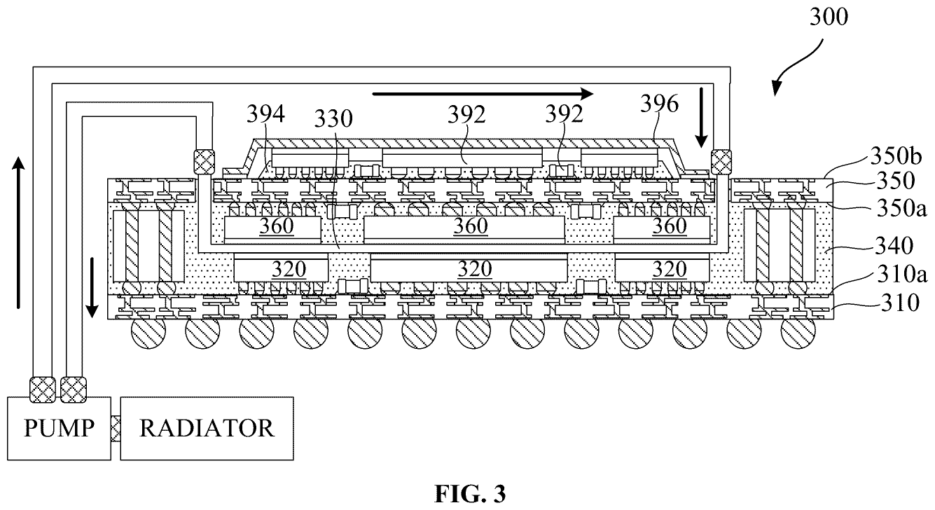

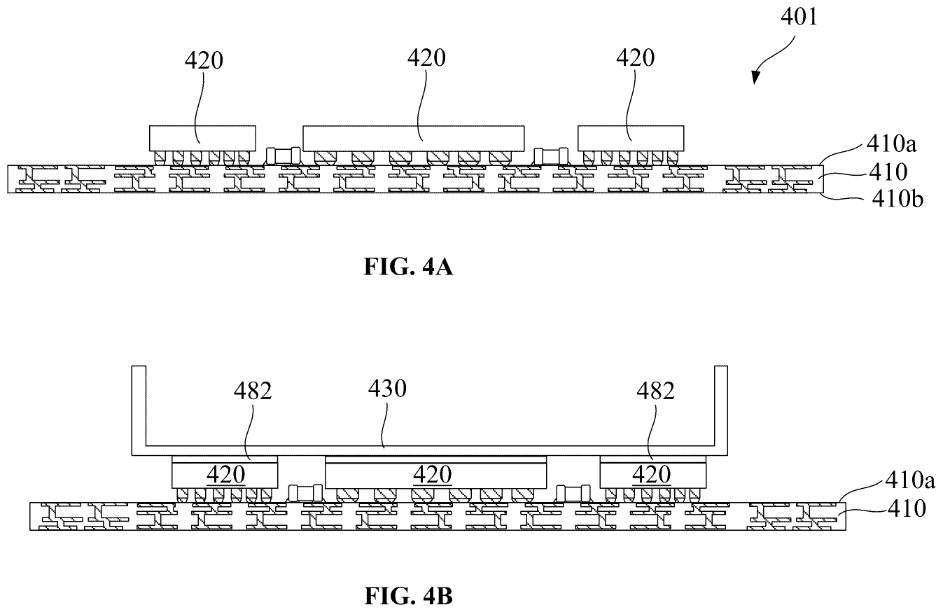

FIG. 1A is a cross-sectional view illustrating a semiconductor package assembly 100 according to an embodiment of the present application. The semiconductor package assembly 100 may include a first semiconductor package, a second semiconductor package, and a cooling pipe 130 sandwiched between the first semiconductor package and second semiconductor package.

As shown in FIG. 1A, the first semiconductor package includes a first substrate 110 and a plurality of first electronic components 120 mounted on the first substrate 110. The first substrate 110 has a front surface 110a and a back surface 110b which are opposite to each other, and the first electronic components 120 are mounted on the front surface 110a of the first substrate 110. The first substrate 110 can provide support and connectivity for electronic components and devices mounted thereon. By way of example, the first substrate 110 may include a printed circuit board (PCB), a carrier substrate, a semiconductor substrate with electrical interconnections, a ceramic substrate, a laminate interposer, a strip interposer, a leadframe, or other suitable substrates. The first substrate 110 may include any structure on or in which an integrated circuit system can be fabricated. In some examples, the first substrate 110 may include redistribution structures having one or more dielectric layers and one or more conductive layers between and through dielectric layers. The conductive layers may define pads, traces and plugs through which electrical signals or voltages can be distributed horizontally and vertically across the redistribution structures.

The first electronic components 120 may include any of a variety of types of semiconductor dice, semiconductor packages, or discrete devices. For example, the first electronic components 120 may include a logic chip such as a central processing unit (CPU) or a graphics processing unit (GPU), a memory device such as a high bandwidth memory (HBM), a digital signal processor (DSP), a radiofrequency (RF) circuit, a wireless baseband system-onchip (SoC) processor, a sensor, an application specific integrated circuit, etc. The first electronic components 120 may be passive components such as resistors, capacitors, inductors, switches, or any other suitable electronic devices. The first electronic components 120 may be mounted on the front surface 110a of the first substrate 110 via solder bumps or similar structures.

Referring to FIG. 1B, a top view illustrating the first substrate 110 is provide according to an exemplary embodiment. A plurality of electronic components 120a, 120b, 120c, 120d, and 120e are mounted on the front surface 110a of the first substrate 110, the electronic component 120a may be a high-performance logic chip such as CPU or GPU which may have high power consumption and generate extensive heat in operation, and the electronic components 120b, 120c, 120d, and 120e may be HBMs. In an example, the electronic components 120a, 120b, 120c, 120d, and 120e may have a same height, such that all of them can thermally contact with a lower surface 130a of the cooling pipe 130 shown in FIG. 1A.

Referring to FIG. 1A, the second semiconductor package includes a second substrate 150 and a plurality of second electronic components 160 mounted on the second substrate 150. The second substrate 150 has a front surface 150a and a back surface 150b opposite to the front surface 150a, and the second electronic components 160 is mounted on the front surface 150a of the second substrate 150. The second electronic components 160 may include any of a variety of types of semiconductor dice, semiconductor packages, or discrete devices, and may be mounted on the front surface 150a of the second substrate 150 via solder bumps or similar structures. The second substrate 150 may be similar as the first substrate 110, and will not be elaborated herein. In an example, a difference existing between the second substrate 150 and the first substrate 110 is that the second substrate 150 includes a first through hole 152a and a second through hole 152b. The first through hole 152a and the second through hole 152b may be formed in a periphery area of the second substrate 150 and extend through the second substrate 150. The first through hole 152a and the second through hole 152b can provide pathways for the cooling pipe 130 to enter or leave the semiconductor package assembly 100, which will be discussed in detail hereafter.

Referring to FIG. 1C, a bottom view illustrating the second substrate 150 is provide according to an exemplary embodiment. A plurality of electronic components 160a, 160b, 160c, 160d, and 160e are mounted on the front surface 150a of the second substrate 150, the electronic component 160a may be a high-performance logic chip such as CPU or GPU, and the electronic components 160b, 160c, 160d, and 160e may be HBMs. The electronic components 160a, 160b, 160c, 160d, and 160e may have a same height, such that all of them can thermally contact with an upper surface 130b of the cooling pipe 130 shown in FIG. 1A.

It could be understood that the types and layout of the electronic components shown in FIGS. 1B and 1C are only exemplary, and may vary according to actual needs.

In some embodiments, as shown in FIG. 1A, a first thermal interface material (TIM) layer 182 is formed between the first electronic components 120 and the lower surface 130a of the cooling pipe 130, and a second TIM layer 184 is formed between the second electronic components 160 and the upper surface 130b of the cooling pipe 130. That is, the first electronic components 120 and the second electronic components 160 are thermally coupled to the cooling pipe 130 via the first TIM layer 182 and the second TIM layer 184 respectively. The first TIM layer 182 and/or the second TIM layer 184 may include solder, indium, silver, an indium/silver alloy, or other suitable materials having a high thermal conductivity. However, the present application is not limited the above embodiment. In some other embodiments, the first electronic components 120 and the second electronic components 160 are directly coupled to the cooling pipe 130, that is, the first TIM layer 182 and the second TIM layer 184 may be omitted.

The cooling pipe 130 is hollow, and thus can form a coolant fluid pathway between the first electronic components 120 and the second electronic components 160, through which a coolant fluid flows to external environment. As the cooling pipe 130 is in thermal contact with the first electronic components 120 and the second electronic components 160, heat generated by the first electronic components 120 and the second electronic components 160 can be dissipated to the external environment by the flowing coolant fluid. In some embodiments, the cooling pipe 130 may be made of a material including or consisting of copper, and the coolant fluid may include water. However, the present application is not limited thereto. In some other embodiments, the cooling pipe 130 may include stainless steel, an alloy or other similar materials having a high thermal conductivity and a sufficient strength, and the coolant fluid may include a liquid flow, a gas flow such as an air flow, or a mixed gas and liquid flow such as a liquid nitrogen flow. The cooling pipe 130 can prevent leakage of the coolant fluid, and improve electrical reliability and safety of the semiconductor package assembly 100.

Referring to FIGS. 1D and 1E, a top view illustrating the cooling pipe 130 is provided in FIG. 1D, and a perspective view illustrating the cooling pipe 130 is provided in FIG. 1E. As shown in FIGS. 1D and 1E, the cooling pipe 130 includes a horizontal portion 130-1, a first vertical portion 130-2 and a second vertical portion 130-3.

The horizontal portion 130-1 may have a rectangular layout, which corresponds to the layouts of the first electronic components 120 and the second electronic components 160. Thus, the first electronic components 120 and the second electronic components 160 can be thermally coupled to a lower surface and an upper surface of the horizontal portion 130-1 of the cooling pipe, respectively. The first vertical portion 130-2 and the second vertical portion 130-3 are in fluid communication with the horizontal portion 130-1 and extend upwards. The first vertical portion 130-2 and the second vertical portion 130-3 may a similar cross-section shape as and align with the first through hole 152a and the second through hole 152b formed in the second substrate 150, such that the first vertical portion 130-2 and the second vertical portion 130-3 can extend through the first through hole 152a and the second through hole 152b, respectively. The first vertical portion 130-2 may serve as an outlet of the cooling pipe 130 to discharge the coolant fluid from the horizontal portion 130-1 to dissipate heat to the external, e.g., to a coolant pool or tank, and the second vertical portion 130-3 may serve as an inlet of the cooling pipe 130 to receive the coolant fluid which has cooled down.

However, the cooling pipe 130 is not limited to the structure and configuration illustrate in FIGS. 1D and 1E. In some other embodiments, the horizontal portion 130-1 may include a plurality of branches extending between the first vertical portion 130-2 and the second vertical portion 130-3, or have a zigzag shape which meanders between the first vertical portion 130-2 and the second vertical portion 130-3. In addition, the outlet portion 130-2 and the inlet portion 130-3 may extend downwards and through two through holes formed in the first substrate 110, or extend horizontally and through two opposite lateral surfaces of the semiconductor package assembly 100. It can be appreciated that the cooling pipe 130 may take other suitable shapes to increase its contact area with the first electronic components 120 and the second electronic components 160.

Continuing referring to FIG. 1A, the cooling pipe 130 is a part of a cooling device which further includes a pump 136 and a radiator 138. As shown in FIG. 1A, a pipe 134a is used to couple an outlet (i.e., the first vertical portion 130-2 shown in FIGS. 1D and 1E) of the cooling pipe 130 to the pump 136, and another pipe 134b is used to couple an inlet (i.e., the second vertical portion 130-3 shown in FIGS. 1D and 1E) of the cooling pipe 130 to the pump 136. According to the configuration of the pump 136, the pipe 134b can bring the coolant fluid into the cooling pipe 130 and the pipe 134a can bring the coolant fluid out of the cooling pipe 130, thereby circulating the coolant fluid within the pipes 134a and 134b and the cooling pipe 130. The pipes 134a and 134b may include polyvinyl chloride (PVC), polyurethane (PU), polyethylene terephthalate glycol (PETG), metal such as copper or aluminum, etc. Further, two valves 132 may be disposed at the inlet and the outlet of the cooling pipe 130 to regulate a flow rate of the coolant fluid within the cooling pipe 130. For example, when the semiconductor package assembly 100 is operating with a high power, i.e., more heat may be generated during the operation, the valves 132 may be regulated to accelerate the flow rate of the coolant fluid. As shown in FIG. 1A, the radiator 138 is coupled to the pump 136 to cool the coolant fluid when it comes into the pump 136. The radiator 138 may be a passive radiator or an active radiator, which can cool the coolant fluid down to a lower temperature. Therefore, the coolant fluid in the cooling pipe 130 may be circulated (represented by arrows in FIG. 1A) and cooled down efficiently through the pump 136 and the radiator 138.

In some embodiments, referring to FIG. 1A, a plurality of first contact pads are formed at a periphery area of the front surface 110a of the first substrate 110 where the first electronic components 120 are not mounted. Correspondingly, a plurality of second contact pads are formed at a periphery area of the front surface 150a of the second substrate 150 where the second electronic components 160 are not mounted. By way of example, the first contact pads and the second contact pads are formed by the redistribution structures formed in the first substrate 110 and the second substrate 150, respectively. Further, a plurality of interconnect structures 170 are electrically connected between the first contact pads and the second contact pads to form electrical connections therebetween, and further to form electrical connections between the first substrate 110 and the second substrate 150. For example, solder bumps may be formed on the first contact pads and the second contact pads to attach the interconnect structures 170 therebetween. In this way, the first semiconductor package and the second semiconductor package may be interconnected to form an integral circuit system.

In the example shown in FIG. 1A, the interconnect structures 170 are e-bar blocks. The e-bar blocks are preformed, and each of them includes at least one conductive pillar (for example, a copper pillar) which is surrounded by a dielectric layer such as an insulative polymeric material or composite. However, the present application is not limited to the example shown in FIG. 1A, and in some other embodiments, the interconnect structures 170 may include metal posts, bonding wires, or similar conductive components.

In some embodiments, referring to FIG. 1A, an encapsulant 140 is formed between the front surface 110a of the first substrate 110 and the front surface 150a of the second substrate 150. The encapsulant 140 encapsulates the first electronic component 120, the second electronic components 160, the interconnect structures 170 and at least a portion of the cooling pipe 130, so as to protect them from the external environment and damages. In an example, the encapsulant 140 encapsulates at least the portion of the cooling pipe 130 which is exposed from the front surface 150a of the second substrate 150. In another example, the encapsulant 140 further fills gaps in the through holes of the second substrate 150 to secure the cooling pipe 130. The encapsulant 140 may include a polymer composite material, such as epoxy resin, epoxy resin with filler, epoxy acrylate with filler, or polymer with proper filler, but the scope of this application is not limited thereto.

In some embodiments, referring to FIG. 1A, a plurality of conductive bumps 190 are formed on a back surface 110b of the first substrate 110. In the example shown in FIG. 1A, the conductive bumps 190 are illustrated as solder bumps, but the present application is not limited thereto. In some other embodiments, the conductive bumps 190 may include conductive pillars, copper balls, etc. In a case where the semiconductor package assembly 100 is mounted on an external device or substrate such as a printed circuit board (PCB), the conductive bumps 190 may be used for electrically connecting the semiconductor package assembly 100 to the external device or substrate.

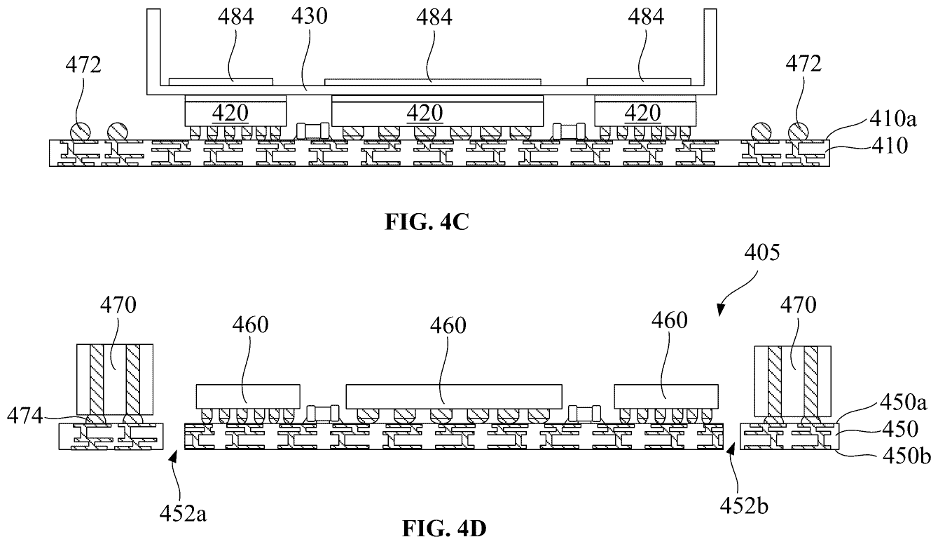

FIG. 2 is a cross-sectional view illustrating a semiconductor package assembly 200 according to another embodiment of the present application. The semiconductor package assembly 200 may have some similar structures and configurations as the semiconductor package assembly 100 shown in FIG. 1A. The similar or same parts between the semiconductor package assembly 200 and the semiconductor package assembly 100 will not be repeated herein.

Specifically, as shown in FIG. 2, the semiconductor package assembly 200 includes a first semiconductor package, a second semiconductor package, and a cooling pipe 230 sandwiched between the first semiconductor package and a second semiconductor package. The first semiconductor package includes a first substrate 210 and at least one first electronic component 220 mounted on a front surface 210a of the first substrate 210. The second semiconductor package includes a second substrate 250 and at least one second electronic component 260 mounted on a front surface 250a of the second substrate 250.

Different from the semiconductor package assembly 100 shown in FIG. 1A, the semiconductor package assembly 200 of FIG. 2 further includes a first heat spreader 225 and a second heat spreader 265. The first heat spreader 225 is disposed between the first electronic component 220 and a lower surface of the cooling pipe 230, and the second heat spreader 265 is disposed between the second electronic component 260 and an upper surface of the cooling pipe 230. The heat spreaders 225 and 265 may include a metal lid made of copper, aluminum, nickel-plated copper, nickel-plated aluminum, or other materials with a high thermal conductivity. In order to further improve thermal conductivities, a first TIM layer 282 is formed between the first electronic component 220 and the first heat spreader 225, and a second TIM layer 284 is formed between the second electronic component 260 and the second heat spreader 265. Further, an encapsulant 240 is formed between the front surface 210a of the first substrate 210 and the front surface 250a of the second substrate 250 to encapsulate the first electronic component 220, the second electronic component 260, and at least a portion of the cooling pipe 230.

The heat spreaders 225 and 265 thermally coupled with the electronic components 220 and 260 can further improve heat dissipation capacity of the semiconductor package assembly 200 of FIG. 2.

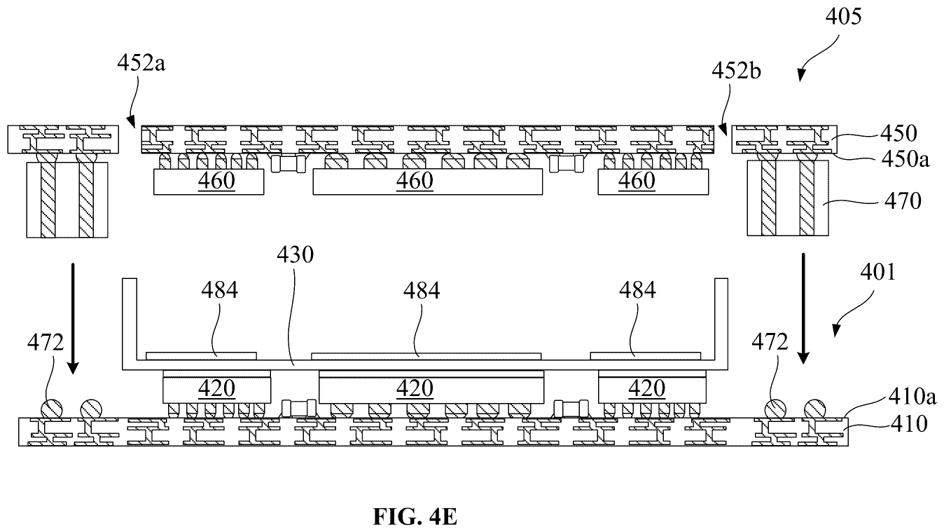

FIG. 3 is a cross-sectional view illustrating a semiconductor package assembly 300 according to another embodiment of the present application. The semiconductor package assembly 300 may have some similar structures and configurations as the semiconductor package assembly 100 shown in FIG. 1A. The similar or same parts between the semiconductor package assembly 300 and the semiconductor package assembly 100 will not be repeated herein.

Specifically, as shown in FIG. 3, the semiconductor package assembly 300 includes a first semiconductor package, a second semiconductor package, and a cooling pipe 330 sandwiched between the first semiconductor package and a second semiconductor package. The first semiconductor package includes a first substrate 310 and at least one first electronic component 320 mounted on a front surface 310a of the first substrate 310. The second semiconductor package includes a second substrate 350 and at least one second electronic component 360 mounted on a front surface 350a of the second substrate 350. Further, an encapsulant 340 is formed between the front surface 310a of the first substrate 310 and the front surface 350a of the second substrate 350 to encapsulate the first electronic component 320, the second electronic component 360, and at least a portion of the cooling pipe 330.

Different from the semiconductor package assembly 100 shown in FIG. 1A, a plurality of third electronic components 392 are mounted on a back surface 350b of the second substrate 350. The third electronic components 392 may include any of a variety of types of semiconductor dice, semiconductor packages, or discrete devices. For example, the third electronic components 392 may be mounted on the back surface 350b of the second substrate 350 via solder bumps or similar structures. Further, an underfill encapsulant 394 may be formed between the third electronic components 392 and the back surface 350b of the second substrate 350. The underfill encapsulant 394 may fill in any gaps between the third electronic components 392 and the second substrate 350, and optionally cover lateral surfaces of the third electronic components 392. The underfill encapsulant 394 may include a polymer composite material, such as epoxy resin, epoxy acrylate, or polymer with or without a filler. The underfill encapsulant 394 may provide mechanical support to the interconnection between the third electronic components 392 and the second substrate 350. Moreover, a heat spreader 396 is thermally coupled to the third electronic components 392. As shown in FIG. 3, the heat spreader 396 is attached on top surfaces of the third electronic components 392. The heat spreader 396 at least partially surrounds the third electronic components 392 mounted on the back surface 350b of the second substrate 350, so as to dissipate heat from the third electronic components 392.

The semiconductor package assembly 300 shown in FIG. 3 is a 3-tier package, which increases the packaging density and incorporates the cooling pipe 330 and the heat spreader 396 to improve its heat dissipation capacity.

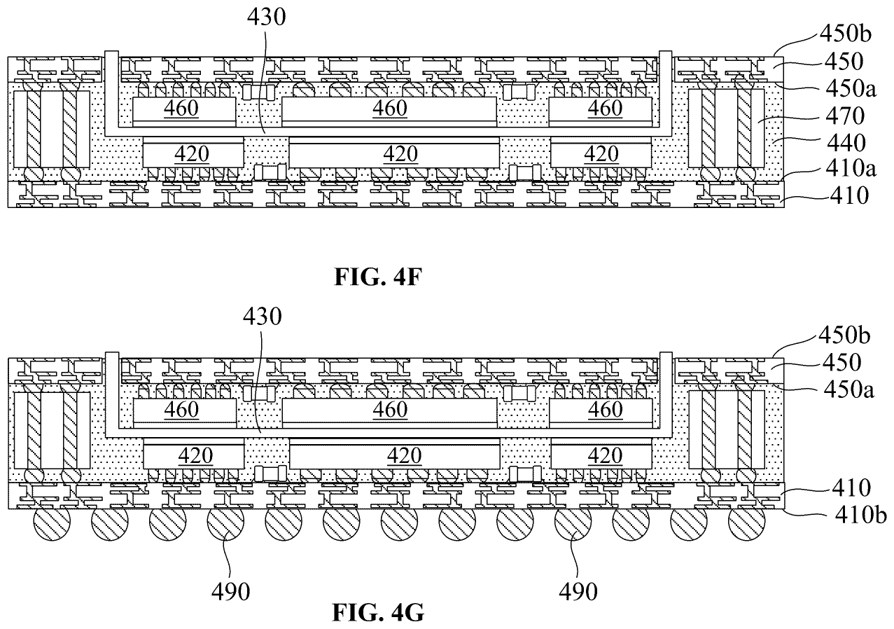

Referring to FIGS. 4A to 4G, various steps of a method for forming a semiconductor package assembly are illustrated according to an embodiment of the present application. For example, the method may be used to form the semiconductor package assembly 100 shown in FIG. 1A. In the following, the method will be described with reference to FIGS. 4A to 4G in more details.

Referring to FIG. 4A, a first semiconductor package 401 is provided. The first semiconductor package 401 includes a first substrate 410 and a plurality of first electronic components 420 mounted on the first substrate 410. The first substrate 410 has a front surface 410a and a back surface 410b which are opposite to each other, and the first electronic components 420 are mounted on the front surface 410a of the first substrate 410. The first substrate 410 may include redistribution structures having one or more dielectric layers and one or more conductive layers between and through dielectric layers. The conductive layers may define pads, traces and plugs through which electrical signals or voltages can be distributed horizontally and vertically across the redistribution structures. The first electronic components 420 may include any of a variety of types of semiconductor dice, semiconductor packages, or discrete devices. For example, the first electronic components 420 may include a logic chip such as a CPU or a GPU, a memory device such as an HBM, etc. The first electronic components 420 may be mounted on the front surface 410a of the first substrate 410 via solder bumps or similar structures.

Referring to FIG. 4B, a first TIM layer 482 is formed on the first electronic components 420, and then a lower surface of a cooling pipe 430 is attached on and thermally coupled to the first electronic components 420 via the first TIM layer 482. In some embodiments, the first TIM layer 482 may include solder, indium, silver, an indium/silver alloy, or other suitable materials. In some embodiments, the first TIM layer 482 may be formed by spray coating, plating, sputtering, or any other suitable metal deposition process. In the example shown in FIG. 4B, the cooling pipe 430 includes a horizontal portion, a first vertical portion and a second vertical portion. A lower surface of the horizontal portion of the cooling pipe 430 is attached on the first electronic components 420 via the first TIM layer 482. The first vertical portion and the second vertical portion are in fluid communication with the horizontal portion and extend upwards.

Referring to FIG. 4C, a second TIM layer 484 is formed on an upper surface of the cooling pipe 430, i.e., an upper surface of the horizontal portion of the cooling pipe 430. The second TIM layer 484 may be similar as the first TIM layer 482 and is formed by a similar process. In some embodiments, a plurality of first contact pads are formed at a periphery area of the front surface 410a of the first substrate 410 where the first electronic components 420 are not mounted. For example, the first contact pads may be formed by the redistribution structures formed in the first substrate 410. Then, a plurality of interconnect bumps 472 such as solder materials are formed on the first contact pads.

Next, referring to FIG. 4D, a second semiconductor package 405 is provided. The second semiconductor package 405 includes a second substrate 450 and a plurality of second electronic components 460 mounted on the second substrate 450. The second substrate 450 has a front surface 450a and a back surface 450b which are opposite to each other, and the second electronic components 460 are mounted on the front surface 450a of the second substrate 450. For example, the second electronic components 460 may be mounted on the front surface 450a of the second substrate 450 via solder bumps or similar structures. In some embodiments, a plurality of second contact pads are formed at a periphery area of the front surface 450a of the second substrate 450 where the second electronic components 460 are not mounted. Then, a plurality of interconnect structures 470 are attached on the second contact pads via interconnect bumps 474 such as solder materials. The interconnect structures 470 may be e-bar blocks, metal posts, or similar conductive components. Further, a first through hole 452a and a second through hole 452b may be formed in the second substrate 450. The first through hole 452a and the second through hole 452b may be formed using laser drilling, mechanical drilling, or other suitable processes. The first through hole 452a and the second through hole 452b can provide pathways for the cooling pipe 430 to enter or leave the semiconductor package assembly to be formed.

Next, referring to FIG. 4E and FIG. 4F, the second semiconductor package 405 is mounted on the first semiconductor package 401 via the cooling pipe 430. Specifically, the second electronic components 460 are thermally coupled to the upper surface of the cooling pipe 430 via the second TIM layer 484, and the interconnect structures 470 are mounted on the front surface 410a of the first substrate 410 via the interconnect bumps 472. Thus, electrical connections between the first substrate 410 and the second substrate 450 can be formed by the interconnect structures 470.

As described above, in some embodiments, the cooling pipe 430 may include the first vertical portion and the second vertical portion extending upwards. Thus, when mounting the second semiconductor package 405 on the first semiconductor package 401, the first vertical portion and the second vertical portion of the cooling pipe 430 are aligned with the first through hole 452a and the second through hole 452b of the second substrate 450, respectively, and then the second semiconductor package 405 is moved downwards to allow the first vertical portion and the second vertical portion of the cooling pipe 430 to pass through the first through hole and the second through hole of the second substrate 450, respectively.

Continuing referring to FIG. 4F, an encapsulant 440 is formed between the front surface 410a of the first substrate 410 and the front surface 450a of the second substrate 450 to encapsulate the first electronic components 420, the second electronic components 460, the interconnect structures 470, and at least a portion of the cooling pipe 430. The encapsulant 440 may include a polymer composite material, such as epoxy resin, epoxy resin with filler, epoxy acrylate with filler, or polymer with proper filler, but the scope of this application is not limited thereto. The encapsulant 440 may be formed using a molding process such as an injection molding process. However, the present application is not limited thereto. In some other embodiments, the encapsulant 440 may be formed using various other molding techniques, including a transfer molding process, a compression molding process, a film-assisted molding (FAM) process, etc.

Next, referring to FIG. 4G, a plurality of conductive bumps 490 are formed on the back surface 410b of the first substrate 410. For example, a solder material may be printed or deposited onto conductive pads exposed from the back surface 410b of the first substrate 410, and then the solder material may be reflowed by heating the material above its melting point to form conductive bumps 490. In some other embodiments, the conductive bumps 490 may be compression bonded or thermocompression bonded onto the contact pads exposed from the back surface 410b of the first substrate 410. In the example shown in FIG. 4G, the conductive bumps 490 are illustrated as solder bumps, but the present application is not limited thereto. In some other embodiments, the conductive bumps 490 may include conductive pillars, copper balls, micro bumps, etc.

In some embodiments, a pump may be coupled with the cooling pipe 430 to circulate a coolant fluid within the cooling pipe 430, and a radiator may be further coupled with the pump to cool the coolant fluid, which will not be elaborated herein.

Although it is only illustrated a single unit of semiconductor package assembly in the steps of FIGS. 4A to 4G, a strip type of semiconductor package assemblies, i.e., various semiconductor package assemblies formed in a package strip, can be made using the processes shown in FIGS. 4A to 4G. Then, a singulation step may be performed to singulate the package strip into individual semiconductor package assemblies.

While the method for making the semiconductor package assembly of the present application is described in conjunction with corresponding FIGS. 4A to 4G, it will be appreciated by those skilled in the art that modifications and adaptations to the processes may be made without departing from the scope of the present invention.

In an example, a first heat spreader may be attached on the first electronic component 420 via the first TIM layer 482 before mounting the cooling pipe 430 on the first semiconductor package as shown in FIG. 4B, and a second heat spreader may be attached on the upper surface of the cooling pipe 430 before forming the second TIM layer 484 on the upper surface of the cooling pipe 430 as shown in FIG. 4C and before mounting the second semiconductor package 405 on the cooling pipe 430 as shown in FIG. 4E. Accordingly, the method described above can be used to form the semiconductor package assembly 200 shown in FIG. 2.

In another example, before the plurality of conductive bumps 490 are formed on the back surface 410b of the first substrate 410 as shown in FIG. 4G, at least one third electronic component may be mounted on a back surface 450b of the second substrate 450, and then a third heat spreader may be attached on the third electronic component. Accordingly, the method described above can be used to form the semiconductor package assembly 300 shown in FIG. 3.

The discussion herein included numerous illustrative figures that showed various portions of a semiconductor package assembly and a method for making the same. For illustrative clarity, such figures did not show all aspects of each exemplary semiconductor package assembly. Any of the example assemblies and/or methods provided herein may share any or all characteristics with any or all other assemblies and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A semiconductor package assembly, comprising:
a first semiconductor package comprising a first substrate and at least one first electronic component mounted on a front surface of the first substrate;
a cooling device comprising a cooling pipe, wherein the cooling pipe is mounted on the first semiconductor package with a lower surface of the cooling pipe thermally coupled to the first electronic component;
a second semiconductor package comprising a second substrate and at least one second electronic component mounted on a front surface of the second substrate, wherein the second semiconductor package is mounted on the cooling pipe with the second electronic component thermally coupled to an upper surface of the cooling pipe; and
an encapsulant formed between the front surface of the first substrate and the front surface of the second substrate to encapsulate the first electronic component, the second electronic component, and at least a portion of the cooling pipe.

2. The semiconductor package assembly of claim 1, wherein the cooling pipe comprises a horizontal portion, a first vertical portion and a second vertical portion, the first electronic component and the second electronic component are thermally coupled to a lower surface and an upper surface of the horizontal portion of the cooling pipe, respectively, and the first vertical portion and the second vertical portion are in fluid communication with the horizontal portion and extend upwards.

3. The semiconductor package assembly of claim 2, wherein the second substrate comprises a first through hole and a second through hole, and the first vertical portion and the second vertical portion of the cooling pipe extend through the first through hole and the second through hole of the second substrate, respectively.

4. The semiconductor package assembly of claim 2, further comprising:
a first thermal interface material (TIM) layer formed between the first electronic component and the lower surface of the horizontal portion of the cooling pipe; and
a second TIM layer formed between the second electronic component and the upper surface of the horizontal portion of the cooling pipe.

5. The semiconductor package assembly of claim 1, wherein the cooling device further comprises:
a pump in fluid communication with the cooling pipe to circulate a coolant fluid within the cooling pipe; and
a radiator in fluid communication with the pump to cool the coolant fluid.

6. The semiconductor package assembly of claim 5, wherein the cooling pipe comprises copper, and the coolant fluid comprises water.

7. The semiconductor package assembly of claim 1, further comprising:
at least one first contact pad formed at a periphery area of the front surface of the first substrate;
at least one second contact pad formed at a periphery area of the front surface of the second substrate; and
at least one interconnect structure disposed between the first contact pad and the second contact pad to form an electric connection therebetween.

8. The semiconductor package assembly of claim 7, wherein the interconnect structure comprises an e-bar block or a metal post.

9. The semiconductor package assembly of claim 1, further comprising:
a plurality of conductive bumps formed on a back surface of the first substrate.

10. The semiconductor package assembly of claim 1, further comprising:
a first heat spreader disposed between the first electronic component and the lower surface of the cooling pipe; and
a second heat spreader disposed between the second electronic component and the upper surface of the cooling pipe.

11. The semiconductor package assembly of claim 1, further comprising:
at least one third electronic component mounted on a back surface of the second substrate; and
a third heat spreader attached on the third electronic component.

12. A method for forming a semiconductor package assembly, comprising:
providing a first semiconductor package, wherein the first semiconductor package comprises a first substrate and at least one first electronic component mounted on a front surface of the first substrate;
mounting a cooling pipe of a cooling device on the first semiconductor package with a lower surface of the cooling pipe thermally coupled to the first electronic component;
mounting a second semiconductor package on the cooling pipe, wherein the second semiconductor package comprises a second substrate and at least one second electronic component mounted on a front surface of the second substrate, and the second electronic component is thermally coupled to an upper surface of the cooling pipe; and
forming an encapsulant between the front surface of the first substrate and the front surface of the second substrate to encapsulate the first electronic component, the second electronic component, and at least a portion of the cooling pipe.

13. The method of claim 12, wherein the cooling pipe comprises a horizontal portion, a first vertical portion and a second vertical portion, and the first vertical portion and the second vertical portion are in fluid communication with the horizontal portion and extend upwards; and
wherein mounting the cooling pipe of the cooling device on the first semiconductor package comprises: attaching the lower surface of the horizontal portion of the cooling pipe onto the first electronic component; and
wherein mounting the second semiconductor package on the cooling pipe comprises: attaching the second electronic component onto the upper surface of the horizontal portion of the cooling pipe.

14. The method of claim 12, wherein the second substrate comprises a first through hole and a second through hole, and
wherein mounting the second semiconductor package on the cooling pipe further comprises:
aligning the first vertical portion and the second vertical portion of the cooling pipe with the first through hole and the second through hole of the second substrate, respectively; and
moving the second semiconductor package downwards to allow the first vertical portion and the second vertical portion of the cooling pipe to pass through the first through hole and the second through hole of the second substrate, respectively.

15. The method of claim 12, further comprising:
forming a first thermal interface material (TIM) layer on the first electronic component before mounting the cooling pipe of the cooling device on the first semiconductor package; and
forming a second TIM layer on the upper surface of the cooling pipe before mounting the second semiconductor package on the cooling pipe.

16. The method of claim 12, further comprising:
coupling a pump with the cooling pipe to circulate a coolant fluid within the cooling pipe; and
coupling a radiator with the pump to cool the coolant fluid.

17. The method of claim 12, wherein the first semiconductor package further comprises at least one first contact pad formed at a periphery area of the front surface of the first substrate, and the second semiconductor package further comprises at least one second contact pad formed at a periphery area of the front surface of the second substrate; and
wherein the method further comprises:
attaching at least one interconnect structure between the first contact pad and the second contact pad to form an electric connection therebetween.

18. The method of claim 12, further comprising:
forming a plurality of conductive bumps on a back surface of the first substrate.

19. The method of claim 12, further comprising:
attaching a first heat spreader on the first electronic component before mounting the cooling pipe of the cooling device on the first semiconductor package; and
attaching a second heat spreader on the upper surface of the cooling pipe before mounting the second semiconductor package on the cooling pipe.

20. The method of claim 12, further comprising:
mounting at least one third electronic component on a back surface of the second substrate; and
attaching a third heat spreader on the third electronic component.
